(19) United States
(12) Patent Application Publication
(10) Pub. No.: US 2025/0022889 A1
(43) Pub. Date: Jan. 16, 2025

(54) ELECTRONIC DEVICE

(71) Applicant: InnoLux Corporation, Miao-Li County (TW)

(72) Inventors: Hua-Hui LIU, Miao-Li County (TW); Tsan-Chu LU, Miao-Li County (TW); Hong-Kang CHANG, Miao-Li County (TW)

(21) Appl. No.: 18/675,676

(22) Filed: May 28, 2024

(30) Foreign Application Priority Data
Jul. 12, 2023 (CN) 202310854022.3

(51) Int. Cl. H01L 27/12

(52) U.S. Cl. CPC H01L 27/124

(57) ABSTRACT

An electronic device is provided. The electronic device includes a substrate, a plurality of first signal lines, a plurality of first driving lines, and a plurality of first conductive lines. The substrate includes an active area. The first signal lines, the first driving lines, and the first conductive lines are disposed in the active area. One end of one of the first driving lines is electrically connected to one of the first signal lines through a through hole. One of the first conductive lines is located in an extension line of the one of the first driving lines. There is a space between an end of the one of the first conductive lines and the end of the one of the first driving lines.

### CROSS REFERENCE TO RELATED APPLICATIONS

This application claims priority of China Patent Application No. 202310854022.3 filed on Jul. 12, 2023, the entirety of which is incorporated by reference herein.

### BACKGROUND OF THE INVENTION

### Field of the Invention

The present disclosure relates to an electronic device, and, in particular, to a design for the configuration of gate lines.

### Description of the Related Art

Electronic devices have become indispensable products in modern life. However, under the tendency of electronic devices to be lighter, thinner, shorter, and smaller in appearance, current display devices still do not meet consumers' expectations in all respects. For example, gate lines and data lines are arranged in different directions (for example, a vertical configuration), so they still occupy a large amount of space in the border area of the non-display area. Therefore, developing a structural design that can meet the trend of the appearance of electronic devices is one of the current research topics in the industry.

### BRIEF SUMMARY OF THE INVENTION

An electronic device is provided. The electronic device includes a substrate, a plurality of first signal lines, a plurality of first driving lines, and a plurality of first conductive lines. The substrate includes an active area. A plurality of first signal lines are disposed in the active area and respectively extend along a first direction. A plurality of first driving lines are disposed in the active area and respectively extend along a second direction. The first direction is different from the second direction. An end of one of the first driving lines is electrically connected to one of the first signal lines through a through hole. A plurality of first conductive lines are disposed in the active area and extend along the second direction. One of the first conductive lines is located in an extension line of the first driving line. There is a space between an end of first conductive line and one end of the first driving line.

A detailed description is given in the following embodiments with reference to the accompanying drawings.

### BRIEF DESCRIPTION OF THE DRAWINGS

FIG. 1 shows a circuit diagram of an electronic device according to a first embodiment of some embodiments of the present disclosure.

FIG. 2 shows a partial plan view corresponding to FIG. 1 according to the first embodiment of some embodiments of the present disclosure.

FIG. 3 shows a plan view of a second embodiment of some embodiments according to the present disclosure.

FIG. 4 shows a cross-sectional view corresponding to the section line A1-A1′ in FIG. 3 according to the second embodiment of some embodiments of the present disclosure.

FIG. 5 shows a circuit diagram of an electronic device according to a third embodiment of some embodiments of the present disclosure.

FIG. 6 shows a partial plan view corresponding to FIG. 5 according to the third embodiment of some embodiments of the present disclosure.

FIG. 7 shows a cross-sectional view corresponding to the section line A2-A2′ in FIG. 6 according to the third embodiment of some embodiments of the present disclosure.

FIG. 8 shows a circuit diagram of an electronic device according to a fourth embodiment of some embodiments of the present disclosure.

FIG. 9 shows a partial plan view corresponding to FIG. 8 according to the fourth embodiment of some embodiments of the present disclosure.

FIG. 10 shows a cross-sectional view corresponding to the section line A3-A3′ in FIG. 9 according to the fourth embodiment of some embodiments of the present disclosure.

FIG. 11 shows a circuit diagram of an electronic device according to a fifth embodiment of some embodiments of the present disclosure.

FIG. 12 shows a partial plan view corresponding to FIG. 11 according to the fifth embodiment of some embodiments of the present disclosure.

FIG. 13 shows a cross-sectional view corresponding to the section line A4-A4′ in FIG. 12 according to the fifth embodiment of some embodiments of the present disclosure.

FIG. 14 shows a circuit diagram of an electronic device according to a sixth embodiment of some embodiments of the present disclosure.

FIG. 15 shows a partial plan view corresponding to FIG. 14 according to the sixth embodiment of some embodiments of the present disclosure.

FIG. 16 shows a cross-sectional view corresponding to the section line A5-A5′ in FIG. 15 according to the sixth embodiment of some embodiments of the present disclosure.

### DETAILED DESCRIPTION OF THE INVENTION

The electronic device of the embodiments of the present disclosure will be described in detail in the following context. It is noted that many different embodiments provided in the following description are used to implement different aspects of the embodiments. The specific elements and configurations described in the following detailed description are set forth in order to clearly describe some embodiments of the present disclosure. It will be apparent that the exemplary embodiments set forth herein are used merely for the purpose of illustration, and are not used to limit the scope of the present disclosure. In addition, the drawings of different embodiments may use like and/or corresponding numerals to denote like and/or corresponding elements in order to clearly describe the present disclosure. However, the use of like and/or corresponding numerals in the drawings of different embodiments is only for the purpose of simply and clearly describing some embodiments of the present disclosure, but does not suggest any correlation between different embodiments.

The present disclosure can be understood by referring to the following detailed description in conjunction with the accompanying drawings. It should be noted that in order to facilitate the reader's understanding and the simplicity of the figures, the multiple drawings in this disclosure only depict a part of the electronic device, and the specific elements in the figures are not drawn according to actual scale. In addition, the number and size of each element in the figure are only for illustration, and are not used to limit the scope of the disclosure. In addition, the number and the size of each element in the figures are only for illustration, and are not used to limit the scope of the disclosure.

It should be appreciated that the elements or devices in the figures of the present disclosure may be present in any form or configuration known to those with ordinary skill in the art. In addition, in the embodiments, relative expressions are used. For example, “lower”, “bottom”, “higher” or “top” are used to describe the position of one element relative to another. It should be appreciated that if a device is flipped upside down, an element that is “lower” will become an element that is “higher”. The descriptions of the exemplary embodiments are intended to be read in connection with the accompanying drawings, which are to be considered part of the entire written description. In addition, the following expression “the first element is disposed on the second element” includes the conditions where the first element and the second element are in direct contact, or one or more other elements are disposed between the first element and the second element so that they are not in direct contact.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, the corresponding features, areas, steps, operations and/or components would be pointed to existence, but not limited to the existence of one or more corresponding features, areas, steps, operations and/or components.

In addition, the relative expressions mentioned in the context, such as “upper”, “lower”, “bottom”, “front”, “back”, “left” or “right”, are used to describe the direction referring to figures. Therefore, the directional terms used are for illustration, and are not used to limit the scope of the disclosure. Each of the figures presents the general features of the methods, structures, and/or materials used in specific embodiments. However, these figures should not be construed as defining or limiting the scope or characteristics covered by these embodiments. For example, for the sake of clarity, the relative size, thickness, and position of each layer, region, and/or structure may be shrink or enlarged.

When a corresponding component (such as a film layer or a region) is referred to as “on another component”, it can be directly disposed on another component, or other components are disposed between the two. On the other hand, when a component is referred to as “directly on another component”, no component is disposed between the two. In addition, when a component is referred to as “on another member”, the two have a vertical relationship in the top view direction. Thus, the component may be on or under the other one, and the up-down relationship depend on the orientation of the device.

In addition, it should be understood that, although the terms “first”, “second”, “third” or the like may be used herein to describe various elements, components, or portions, these elements, components, or portions should not be limited by these terms. These terms are only used to distinguish one element, component, region, layer or portion from another element, component, region, layer or portion. Thus, a first element, component, region, layer or portion discussed below could be termed a second element, component, region, layer or portion without departing from the teachings of the present disclosure.

The terms “about”, “substantially”, “equal”, or “same” generally mean within 10% of a given value or range, or mean within 5%, 3%, 2%, 1%, or 0.5% of a given value or range. The given value here is an approximate value. That is, “about”, “substantially” may be still implied without a specific description of “about”, “substantially”. In addition, the phrase “in a range from a first value to a second value” indicates the range includes the first value, the second value, and other values in between.

It should be appreciated that, in the embodiments described in the following, the several features in different embodiments may be replaced, reorganized, and mixed to complete other embodiments without departing from the spirit of the present disclosure. The features of the various embodiments can be used in any combination as long as they do not depart from the spirit and scope of the present disclosure.

In the present disclosure, the thickness, length, and width can be measured by using an optical microscope, and the thickness can be measured by the cross-sectional image in the electron microscope, but it is not limited thereto. In addition, a certain error may be present in a comparison with any two values or directions. If the first value is equal to the second value, it implies that an error of about 10% between the first value and the second value may be present. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Unless defined otherwise, all terms (including technical and scientific terms) used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined in the present disclosure.

The embodiment of the present disclosure utilizes a T-shaped wire structure, so that the direction of the gate driving wire for transmitting the gate signal and the wire for transmitting the data signal are in the same direction. In this way, the data driver and the gate driver may be arranged on the same side, so as to achieve the purpose of narrow frame. In addition, the embodiments of the present disclosure further reduce the optical unevenness (mura) caused by the wiring structure by arranging the first conductive line (also referred to a dummy signal line) parallel to the data line. Furthermore, the embodiment of the present disclosure further reduces optical unevenness (mura) caused by different voltages by arranging the second conductive line to cover the through hole at the end of the gate driving line.

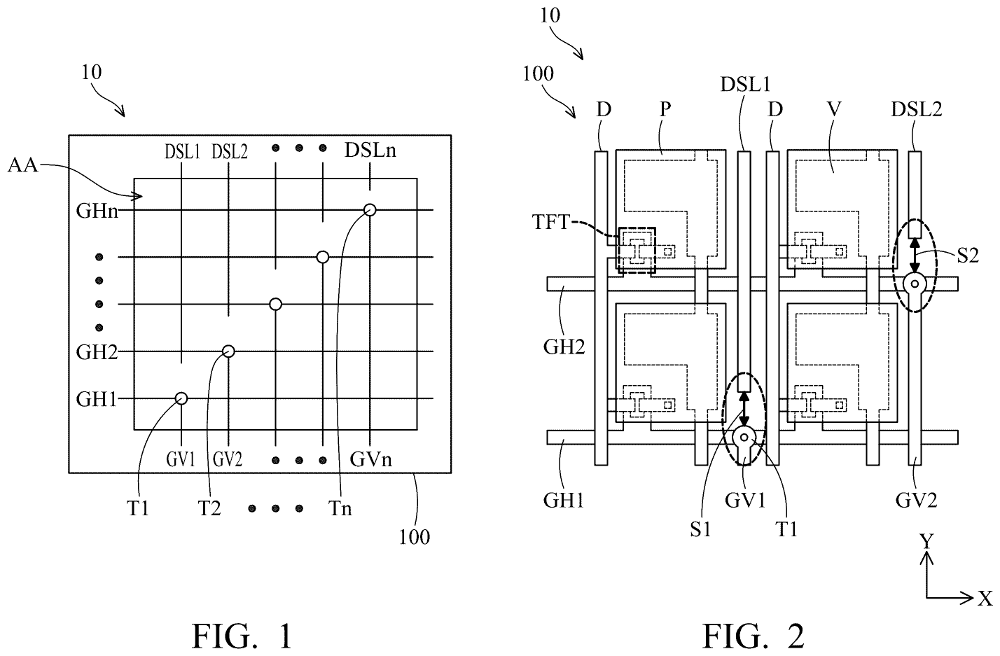

First, a first embodiment of some embodiments of the present disclosure will be described below. FIG. 1 shows a circuit diagram of the electronic device 10, and FIG. 2 shows a partial plan view corresponding to FIG. 1.

Please refer to FIG. 1, FIG. 1 shows a circuit diagram of the electronic device 10. It should be noted that, in order to clearly describe the features of the present disclosure, the circuit diagram of FIG. 1 only shows a portion of elements.

In some embodiments, the electronic device 10 may include a display device, a backlight device, an antenna device, a sensing device or a splicing device, but not limited thereto. The electronic device may be a bendable or flexible electronic device. Electronic devices may include passive components and active components, such as capacitors, resistors, inductors, diodes, transistors, and the like. The diodes may include light emitting diodes or photodiodes, but are not limited thereto.

The display device may be a non-self-luminous display device or a self-luminous display device. Self-luminous display devices may include light emitting diodes, such as organic light emitting diodes (OLEDs), submillimeter light emitting diodes (mini LEDs), micro light emitting diodes (micro LEDs) or quantum dots light emitting diode (quantum dot LED), but not limited thereto. The non-self-luminous display device may be an electrowetting display device, an electrophoretic display device, or a liquid crystal display device, but is not limited thereto. The liquid crystal display device may be a twisted nematic (TN) type liquid crystal display device, a super twisted nematic (STN) type liquid crystal display device, a double layer super twisted nematic (DSTN)) type liquid crystal display device, vertical alignment (VA) type liquid crystal display device, horizontal electric field effect (In-Plane Switching, IPS) type liquid crystal display device, cholesterol type liquid crystal display device, blue phase type liquid crystal display device, fringe field effect (FFS) type liquid crystal display device, low temperature polysilicon liquid crystal display device (LTPS) or any other suitable liquid crystal display device.

The antenna device may be a liquid crystal type antenna device or a non-liquid crystal type antenna device, and the sensing device may be a sensing device for sensing capacitance, light, thermal energy or ultrasonic waves, but not limited thereto. The splicing device may be, for example, a display splicing device or an antenna splicing device, but is not limited thereto. It should be noted that the electronic device may be any permutation and combination of the aforementioned, but not limited thereto. In the following, the display device is used as an electronic device to illustrate the content of the disclosure, but the disclosure is not limited thereto.

As shown in FIG. 1, the electronic device 10 includes a substrate 100, which includes an active area AA and an edge area (not shown) other than the active area AA. As shown in FIG. 1, the electronic device 10 further includes a plurality of signal lines GH1, GH2 . . . GHn and a plurality of driving lines GV1, GV2 . . . GVn. The signal lines GH1, GH2 . . . GHn may be referred to gate signal lines, and the driving lines GV1, GV2 . . . GVn may be referred to gate driving lines, and both of them may be configured to transmit scan signals. It should be noted that although the gate signal lines and gate driving lines are taken as examples in this disclosure, in some embodiments, the plurality of signal lines GH1, GH2 . . . GHn and the plurality of driving lines GV1, GV2 . . . GVn in FIG. 1 may also be respectively configured as data signal lines and data driving lines for transmitting data signals.

As shown in FIG. 1, the signal line GH1 is electrically connected to the driving line GV1 through the through hole T1, the signal line GH2 is electrically connected to the driving line GV2 through the through hole T2 . . . the signal line GHn is electrically connected to the driving line GVn through the through hole Tn. More specifically, the signal line GH1, the signal line GH2 . . . and the signal line GHn extend from the edge area on one side (for example, the left side of the electronic device 10) to the edge area on the other side (for example, the right side of the electronic device 10) via the active area AA. The driving line GV1, the driving line GV2 . . . the driving line GVn extend upward from the edge area on the other side (for example, the lower side of the electronic device 10), and the ends thereof are electrically connected to the signal line GH1, signal line GH2 . . . signal line GHn via the through hole T1, the through hole T2 . . . the through hole Tn, respectively. That is, the signal line GH1, the signal line GH2 . . . the signal line GHn start from the edge area and end at the edge area, while the driving line GV1, the driving line GV2 . . . the driving line GVn start from the edge area but end at the active area AA. That is, the signal line GH1, the signal line GH2 . . . the signal line GHn and the driving line GV1, the driving line GV2 . . . the driving line GVn are at least partially disposed in the active area AA.

As shown in FIG. 1, the electronic device 10 further includes a plurality of first conductive lines DSL1, DSL2 . . . DSLn. The plurality of first conductive lines DSL1, DSL2 . . . DSLn may be regarded as dummy signal lines, and are used to reduce the manufacturing and electrical problems caused by the difference in stack structure caused by the original T-shaped wiring design. The first conductive line DSL1, the first conductive line DSL2 . . . the first conductive line DSLn may be arranged corresponding to the signal line GH1, the signal line GH2 . . . the signal line GHn, and may also be arranged corresponding to the data lines (not shown), but not limited thereto. It should be noted that the first conductive line DSL1, the first conductive line DSL2 . . . the first conductive line DSLn correspond to the driving line GV1, the driving line GV2 . . . the driving line GVn. That is, the first conductive line DSL1, the first conductive line DSL2 . . . the first conductive line DSLn start from the edge area but end in the active area AA. That is, the first conductive line DSL1, the first conductive line DSL2 . . . the first conductive line DSLn are at least partially disposed in the active area AA.

In some embodiments, adjacent two driving lines have different lengths. For example, the length of the driving line GV1 is less than that of the driving line GV2. The lengths of two adjacent first conductive lines are also different. For example, the length of the first conductive line DSL1 is greater than the length of the first conductive line DSL2. In some embodiments, the length of the driving line and the length of the first conductive line show an opposite trend. For example, as shown in the subsequent FIG. 2, along the first direction X, as the length of the driving line becomes greater (for example, the driving line GV2 is longer than the driving line GV1), and the length of the first conducting line becomes shorter (for example, the first conducting line DSL2 is shorter than the first conducting line DSL1).

Next, please referring to FIG. 2, FIG. 2 shows a partial plan view corresponding to FIG. 1. It should be noted that, in order to clearly describe the features of this disclosure, FIG. 2 only shows a portion of elements while omitting other film layers and/or elements (such as dielectric layers, etc.).

As shown in FIG. 2, the electronic device 10 includes a substrate 100. As shown in FIG. 2, the electronic device 10 includes a signal line GH1 and a signal line GH2 disposed on the substrate 100 and extending along the first direction X. The electronic device 10 also includes a driving line GV1 and a driving line GV2 disposed on the substrate 100 and extending along the second direction Y. The electronic device 10 also includes a plurality of data lines D disposed on the substrate 100 and extending along the second direction Y. The electronic device 10 also includes a first conductive line DSL1 and a first conductive line DSL2 disposed on the substrate 100 and extending along the second direction Y. In some embodiments, the first direction X is different from the second direction Y. For example, the first direction X is perpendicular to the second direction Y in this embodiment.

In some embodiments, the driving line GV1, the driving line GV2, the data line D, the first conductive line DSL1, and the first conductive line DSL2 may be located in the same layer, and located on the signal line GH1, and the signal line GH2. In some embodiments, the data line D is parallel to and not overlapped with the driving line GV1, the driving line GV2, the first conductive line DSL1, and the first conductive line DSL2.

In some embodiments, the first conductive line DSL1 is not connected to the driving line GV1. The first conduction line DSL1 is located in the extension line of the driving line GV1, and the driving line GV1 is also located in the extension line of the first conduction line DSL1. Moreover, the first conductive line DSL1 corresponds to the driving line GV1 through the space S1. That is, there is a space S1 between an end of the first conductive line DSL1 and an end of the driving line GV1 close to the end of the first conductive line DSL1.

In some embodiments, the first conductive line DSL2 is not connected to the driving line GV2. The first conductive line DSL2 is located in the extension line of the driving line GV2, and the driving line GV2 is also located in the extension line of the first conductive line DSL2. Moreover, the first conductive line DSL2 corresponds to the driving line GV2 through the space S2. That is, there is a space S2 between the end of the first conductive line DSL2 and the end of the driving line GV2 close to the end of the first conductive line DSL2. According to actual needs, the spacing S1 and the spacing S2 may be the same or different.

In some embodiments, the signal line GH1 extending along the first direction X is electrically connected to the driving line GV1 located in different layers and extending along the second direction Y through the through hole T1. In some embodiments, the signal line GH2 extending along the first direction X is electrically connected to the driving line GV2 located in different layers and extending along the second direction Y through the through hole T2. The gate signals generated by the gate drivers (not shown) may be transmitted to the corresponding signal lines GH1 . . . GHn through the driving lines GV1 . . . GVn.

For the convenience of description, the space S1 and the space S2 are sometimes collectively referred to as a plurality of spaces S or the space S. The first conducting line DSL1 and the first conducting line DSL2 are referred to as a plurality of first conducting lines DSL or the first conductive line DSL. The driving line GV1 and the driving line GV2 are collectively referred to as a plurality of driving lines GV or the driving line GV. The signal line GH1 and the signal line GH2 are collectively referred to as a plurality of signal lines GH or the signal line GH. The through hole T1 and the through hole T2 are collectively referred to as a plurality of through holes T or the through hole T.

As shown in FIG. 2, the electronic device 10 includes a plurality of thin film transistors TFT for controlling whether the data signal is written into the pixel unit. In some embodiments, the thin film transistors may include switching transistors, driving transistors, reset transistors, transistor amplifiers or other suitable thin film transistors, but not limited to this. In some embodiments, the data line D is connected to the source of the thin film transistor TFT, and the signal line GH is connected to the gate of the thin film transistor TFT.

It should be understood that the number of thin film transistors is not limited to what is shown in the figure. According to different embodiments, the electronic device 10 may have other suitable numbers or types of thin film transistors. Furthermore, the types of TFTs may include top gate TFTs, bottom gate TFTs, dual gate or double gate TFTs or combinations thereof. According to some embodiments, the thin film transistor may be further electrically connected to the pixel electrode P, but is not limited thereto. It should be noted that the thin film transistor may exist in various forms known to those skilled in the art, and the detailed structure of the thin film transistor will not be repeated here.

As shown in FIG. 2, the electronic device 10 includes a plurality of common electrodes V, and the common electrodes V may be at least partially overlapped with the pixel electrodes P to form capacitors. In some embodiments, the signal line GH may control whether the data of the data line D is input to the pixel electrode P.

As above, the signal line GH is electrically connected to the driving line GV in different layers through the through hole T to form a T-shaped wiring structure, so as to reduce the area of the edge area and achieve the effect of a narrow frame.

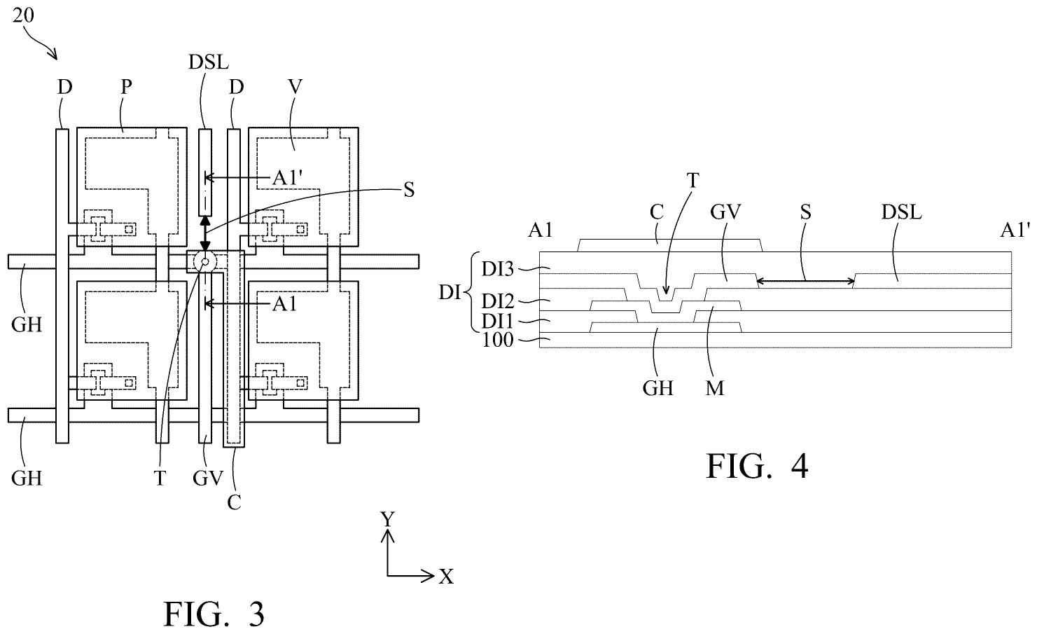

Next, a second embodiment of some embodiments of the present disclosure will be described below. FIG. 3 shows a plan view, and FIG. 4 shows a cross-sectional view corresponding to section line A1-A1′ in FIG. 3. The second embodiment is similar to the first embodiment, and the difference is that the electronic device 20 further includes a second conductive line C disposed on the driving line GV. In the embodiment of FIG. 3, the second conductive line C covers the through hole T, covers a portion of the data line D, and extends along the second direction Y. The second conductive line C and the first conductive line DSL may receive the same voltage, but the present disclosure is not limited thereto. By making the second conductive line C receive the same voltage as the first conductive line DSL, the display difference caused by the different voltages of the driving line GV, the signal line GH and the first conductive line DSL may be reduced and the optical unevenness caused by T-shaped wiring structure may be further reduced.

In the embodiment shown in FIG. 3, a portion of the second conductive line C extends along the first direction X, and another portion extends along the second direction Y. That is, the second conductive line C presents (but is not limited to) an inverted L shape. In addition, FIG. 4 shows a cross-sectional view corresponding to the section line A1-A1′ in FIG. 3 in more detail. In the embodiment shown in FIG. 4, the signal line GH, the conductive layer M, and the driving line GV are disposed on the substrate 100. In the embodiment shown in FIG. 4, the signal line GH is electrically connected to the conductive layer M and the driving line GV through the through hole T. In some embodiments, the electronic device 20 may not include the conductive layer M, so that the signal line GH may be directly electrically connected to the driving line GV through the through hole T. In the embodiment shown in FIG. 4, the second conductive line C covers the through hole T and is located in a portion of the driving line GV. In the embodiment of FIG. 4, there is a space S between the driving line GV and the first conductive line DSL located in the same layer. As mentioned above, it may be seen from FIG. 4 that the signal line GH is electrically connected to the driving line GV through the through hole T.

In the embodiment of FIG. 4, a dielectric layer DI is also disposed on the substrate 100, which includes a first dielectric layer DI1, a second dielectric layer DI2 on the first dielectric layer DI1, and a third dielectric layer DI3 on the second dielectric layer DI2, but the present disclosure is not limited thereto.

In some embodiments, according to different requirements, the substrate 100 may include or be a rigid base, a flexible base or a combination of the aforementioned bases, but the disclosure is not limited thereto. In some embodiments, the material of the rigid base may include or may be a wafer, glass, quartz, ceramics, sapphire, other suitable materials, or a combination of the aforementioned materials, but the present disclosure is not limited thereto. In some embodiments, the material of the flexible base may include or may be polycarbonate (PC), polyimide (PI), polypropylene (PP), polyethylene terephthalate (PET), other suitable materials, or a combination of the aforementioned materials, but the present disclosure is not limited thereto. In some embodiments, the substrate 100 may be a single-layer or multi-layer structure, but the present disclosure is not limited thereto. In some embodiments, the substrate 100 may include or may be a transparent base, a semi-transparent base or an opaque base.

In some embodiments, the signal line GH, the conductive layer M, the driving line GV, and the first conductive line DSL may include conductive materials, such as one or more metals, metal nitrides, conductive metal oxides, suitable materials or a combination of the above. The metal may include molybdenum, tungsten, titanium, tantalum, platinum or hafnium, but is not limited thereto. The metal nitride may include molybdenum nitride, tungsten nitride, titanium nitride and tantalum nitride, but is not limited thereto. The conductive metal oxide may include ruthenium oxide and indium tin oxide, but is not limited thereto. It should be noted that at least one of the signal line GH, the conductive layer M, the driving line GV, and the first conductive line DSL may be a multi-layer structure. For example, the multi-layer structure may be at least two metals such as molybdenum, aluminum, titanium, and copper are simultaneously included, but is not limited thereto.

In some embodiments, the signal line GH, the conductive layer M, the driving line GV, the first conductive line DSL, and the second conductive line C may be formed by a deposition method, a sputtering method, a resistance heating evaporation method, an electron beam evaporation method, or any other suitable method. The deposition method includes chemical vapor deposition (CVD), physical vapor deposition (PVD), and the like.

In some embodiments, the dielectric layer DI may be a single-layer or multi-layer structure. The dielectric layer DI may include dielectric materials, such as silicon oxide, silicon nitride, silicon oxynitride, high dielectric constant (high-k) dielectric materials, or any other suitable dielectric materials, or combinations thereof, but is not limited thereto. The high-k dielectric materials may include metal oxides, metal nitrides, metal silicides, transition metal oxides, transition metal nitrides, transition metal silicides, metal oxynitrides, metal aluminate, zirconium silicate, zircoaluminate, and the like, but are not limited thereto. For example, high-k dielectric materials may be LaO, AlO, ZrO, TiO, Ta₂O₅, Y₂O₃, SrTiO₃(STO), BaTiO₃(BTO), BaZrO, HfO₂, HfO₃, HfZrO, HfLaO, HfSiO, HfSiON, LaSiO, AlSiO, HfTaO, HfTiO, HfTaTiO, HfAlON, (Ba,Sr)TiO₃(BST), Al₂O₃, other suitable high-k dielectric materials, or combinations thereof, but not limited thereto.

In some embodiments, the dielectric layer DI may be formed by a deposition method, such as chemical vapor deposition (CVD), atomic layer deposition (ALD), spin coating method or other suitable methods, but not limited thereto. The chemical vapor deposition method may be, for example, low pressure chemical vapor deposition (LPCVD), low temperature chemical vapor deposition (LTCVD), rapid temperature chemical vapor deposition (RTCVD), plasma enhanced chemical vapor deposition (PECVD), and the like.

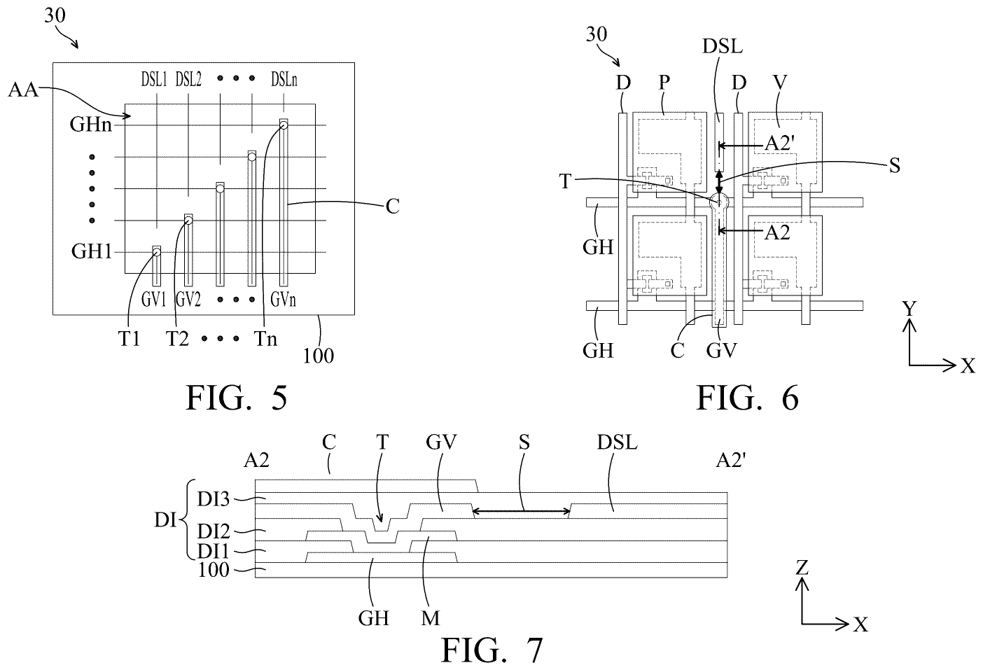

Next, a third embodiment of some embodiments of the present disclosure will be described below. FIG. 5 shows a circuit diagram of the electronic device, FIG. 6 shows a partial plan view corresponding to FIG. 5, and FIG. 7 shows a cross-sectional view corresponding to section line A2-A2′ in FIG. 6. The third embodiment is similar to the second embodiment and the different is that the second conductive line C of the electronic device 30 does not cover the data line D but covers the through hole T and the driving line GV and extends along the second direction Y. By covering the through hole T and the driving line GV, the display difference caused by the different voltages of the driving line GV, the signal line GH and the first conductive line DSL may be reduced, and the occurrence of optical unevenness caused by the T-shaped wire structure may be further reduced.

Specifically, as shown in the embodiment of FIG. 5, as the lengths of the two adjacent driving lines GV are different (for example, the length of the driving line GV1 is less than the length of the driving line GV2), the lengths of the adjacent two second conductive line C are also different (for example, the length of the second conductive line C covering the driving line GV1 is less than the length of the second conductive line C covering the driving line GV2). In the embodiment of FIG. 5, the second conductive line C only extends along the second direction Y. As shown in the embodiment of FIG. 6, the second conductive line C extends from the through hole T and covers the driving line GV. In addition, FIG. 7 shows cross-sectional view in more detail corresponding to the section line A2-A2′ in FIG. 6. FIG. 7 is similar to FIG. 4, except that the second conductive line C covers the portion of the driving line GV located in the active area AA, and thus it will not be repeated here.

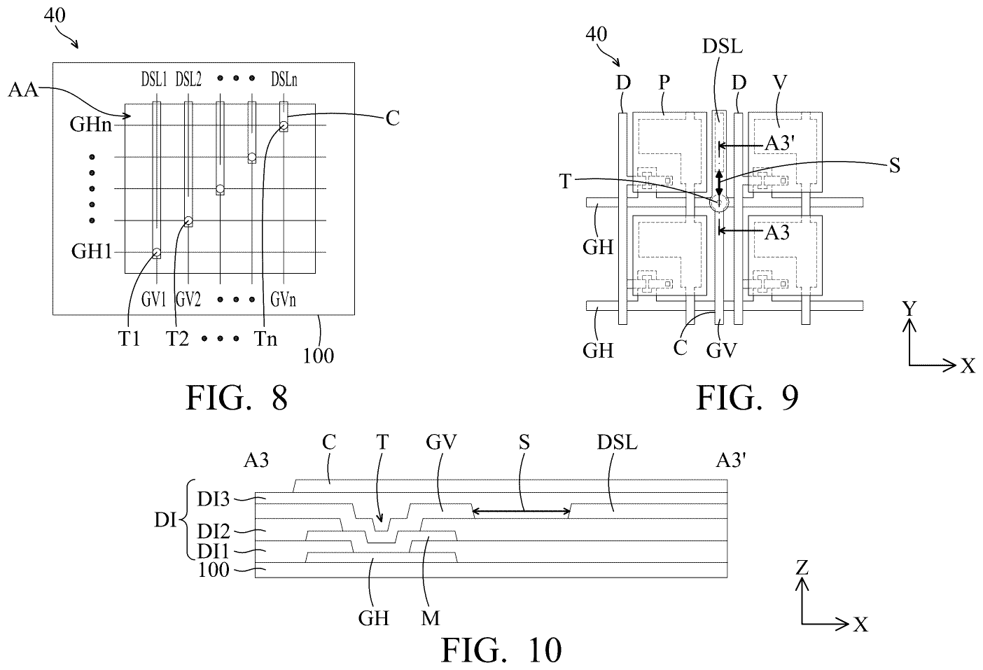

Next, a fourth embodiment of some embodiments of the present disclosure will be described below. FIG. 8 shows a circuit diagram of the electronic device, FIG. 9 shows a partial plan view corresponding to FIG. 8, and FIG. 10 shows a cross-sectional view corresponding to section line A3-A3′ in FIG. 9. The fourth embodiment is similar to the third embodiment, and the difference is that the second conductive line C of the electronic device 40 covers the through hole T, the space S and the first conductive line DSL and extends along the second direction Y. By covering the through hole T and the first conductive line DSL, the display difference caused by the voltage difference between the driving line GV, the signal line GH and the first conductive line DSL may be reduced, and the optical unevenness caused by the T-shaped wire structure may be further reduced.

Specifically, as shown in the embodiment of FIG. 8, as the lengths of the two adjacent first conductive lines DSL are different (for example, the length of the first conductive line DSL1 is greater than the length of the first conductive line DSL2). The lengths of two adjacent second conductive lines C are also different (for example, the length of the second conductive line C covering the first conductive line DSL1 is greater than the length of the second conductive line C covering the first conductive line DSL2). As shown in the embodiment of FIG. 9, the second conductive line C extends from the through hole T and covers the space S and the first conductive line DSL. In addition, FIG. 10 shows a cross-sectional view in more detail corresponding to the section line A3-A3′ in FIG. 9. FIG. 10 is similar to FIG. 4, except that the conductive line DSL covers a portion of the driving line GV (such as the through hole T), the space S and the first conductive line DSL, and it thus will not be repeated here.

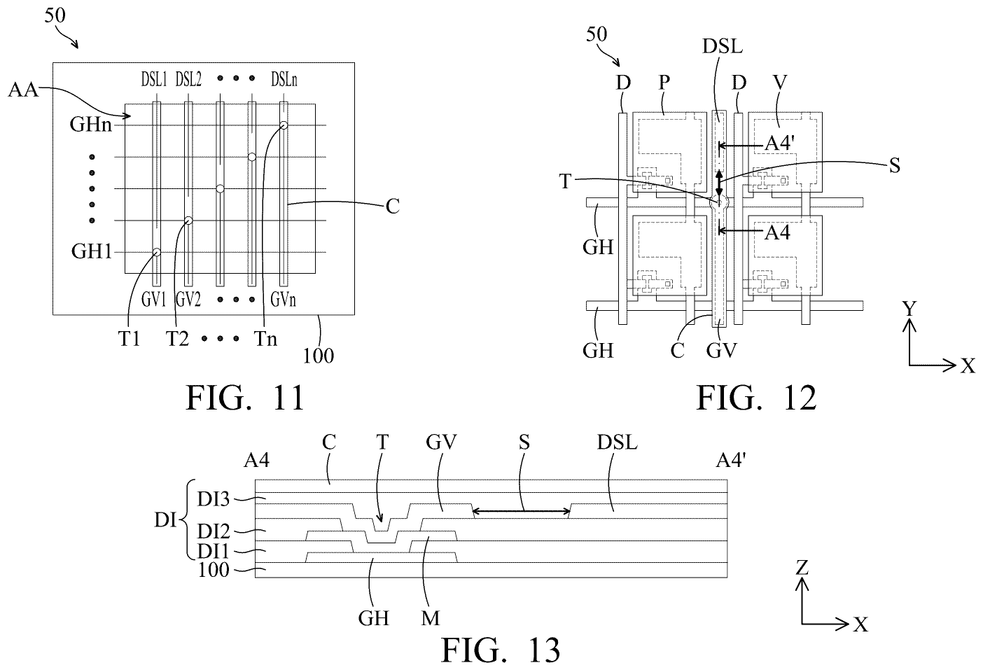

Next, a fifth embodiment of some embodiments of the present disclosure will be described below. FIG. 11 shows a circuit diagram of the electronic device, FIG. 12 shows a partial plan view corresponding to FIG. 11, and FIG. 13 shows a cross-sectional view corresponding to section line A4-A4′ in FIG. 12. The fifth embodiment is similar to the fourth embodiment, and the different is that the second conductive line C of the electronic device 50 covers the driving line GV, the through hole T, the space S and the first conductive line DSL and extends along the second direction Y. By the second conductive line C covering the through hole T, the driving line GV, and the first conductive line DSL, the display difference caused by the different voltages of the driving line GV, the signal line GH, and the first conductive line DSL may be reduced, and the optical unevenness caused by T-shaped wire structure may be further reduced.

Specifically, as shown in the embodiment of FIG. 11, since the second conductive line C extends from the first driving line GV1 to the first conductive line DSL1 through the through hole T1, its length change is the same as that of the first driving line GV1. It is not directly related to the first conductive line DSL1. For example, the second conductive line C may have a fixed length. As shown in the embodiment of FIG. 12, the second conductive line C extends from the driving line GV through the through hole T and the space S and covers the first conductive line DSL. In addition, FIG. 13 shows a cross-sectional view in more detail corresponding to the section line A4-A4′ in FIG. 12. FIG. 13 is similar to FIG. 4, except that the second conductive line C covers the driving line GV located in the active area AA (such as the through hole T), the space S and the first conductive line DSL, and thus it will not be repeated here.

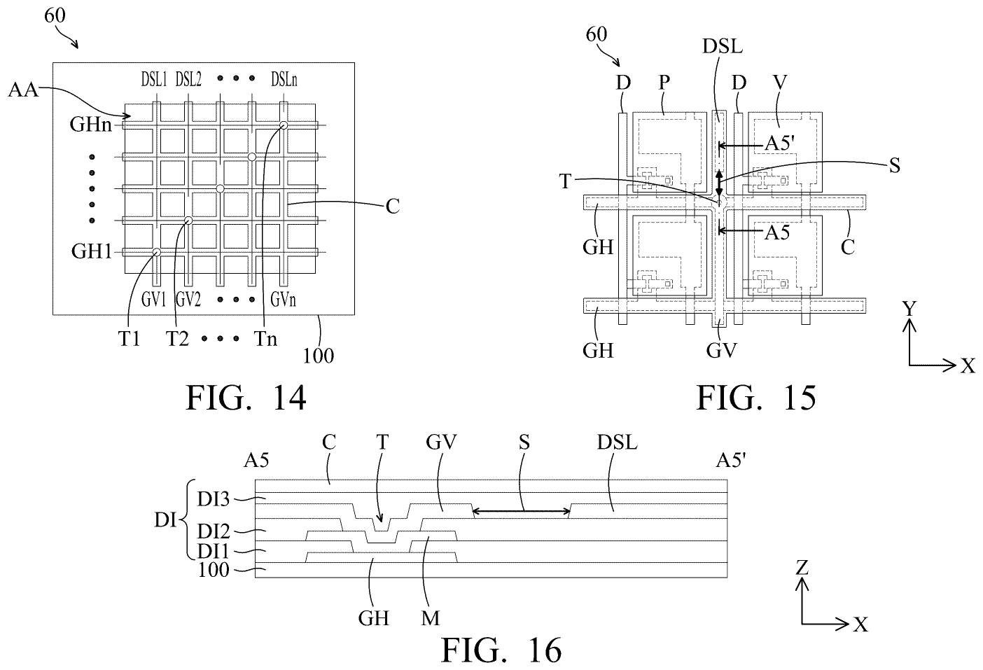

Next, a sixth embodiment of some embodiments of the present disclosure will be described below. FIG. 14 shows a circuit diagram of the electronic device, FIG. 15 shows a partial plan view corresponding to FIG. 14, and FIG. 16 shows a cross-sectional view corresponding to section line A5-A5′ in FIG. 15. The sixth embodiment is similar to the fifth embodiment, and the difference is that the second conductive line C of the electronic device 60 further covers the signal line GH (extending along the first direction X) in addition to the driving line GV, the through hole T, the space S and the first conductive line DSL. By the second conductive line C covering the through hole T, the signal line GH, the driving line GV and the first conductive line DSL, the display difference caused by the voltage difference between the driving line GV, the signal line GH and the first conductive line DSL may be reduced, and the optical unevenness caused by the T-shaped wire structure may be further reduced.

Specifically, as shown in the embodiment shown in FIG. 14, the second conductive line C extends along the first direction X and the second direction Y at the same time. For example, when the second conductive line C extends along the first direction X, the second conductive line C covers the portion of the signal line GH located in the active area AA. When the second conductive line C extends along the second direction Y, the second conductive line C extends from the first driving line GV1 to the first conductive line DSL1 through the through hole T1. That is, the second conductive lines C present a grid shape. As shown in the embodiment of FIG. 15, in addition to extending from the driving line GV through the through hole T and the space S and covering the first conductive line DSL, the second conductive line C also covers all the signal lines GH. In addition, FIG. 16 shows a cross-sectional view in more detail corresponding to the section line A5-A5′ in FIG. 15. Since the section line A5-A5′ in FIG. 15 is similar to the section line A4-A4′ in FIG. 13 (along the second direction Y), the cross-sectional view in FIG. 16 is similar to that in FIG. 13, and thus it will not be repeated here.

To sum up, according to some embodiments of the present disclosure, the signal line and the driving line are formed into a T-shaped wire structure, so that the driving device may be arranged on the same side, thereby achieving the purpose of narrow frame. In addition, the first conductive line is also used to reduce the problems caused by the stack difference caused by the original T-shaped wire structure. Moreover, the second conductive line is further used to cover the through hole to improve the optical unevenness caused by the voltage difference.

While the embodiments and the advantages of the present disclosure have been described above, it should be understood that those skilled in the art may make various changes, substitutions, and alterations to the present disclosure without departing from the spirit and scope of the present disclosure. It should be noted that different embodiments may be arbitrarily combined as other embodiments as long as the combination conforms to the spirit of the present disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

What is claimed is:

1. An electronic device, comprising:
a substrate including an active area;
a plurality of first signal lines disposed in the active area and respectively extending along a first direction;
a plurality of first driving lines disposed in the active area and respectively extending along a second direction,
wherein the first direction is different from the second direction,
wherein an end of one of the plurality of first driving lines is electrically connected to one of the plurality of first signal lines through a through hole; and
a plurality of first conductive lines disposed in the active area and extending along the second direction,
wherein one of the plurality of first conductive lines is located in an extension line of the one of the plurality of first driving lines,
wherein there is a space between an end of the one of the plurality of first conductive lines and the end of the one of the plurality of first driving lines.

2. The electronic device as claimed in claim 1, further comprising: a plurality of second conductive lines disposed on the plurality of first conductive lines and respectively extending along the second direction,
wherein a portion of one of the plurality of second conductive lines covers the through hole.

3. The electronic device as claimed in claim 2, wherein the one of the plurality of second conductive lines covers the one of the plurality of first driving lines.

4. The electronic device as claimed in claim 2, wherein the one of the plurality of second conductive lines covers the one of the plurality of first conductive lines and the space.

5. The electronic device as claimed in claim 2, wherein the one of the plurality of second conductive lines covers the one of the plurality of first driving lines, the space, and the one of the plurality of first conductive lines.

6. The electronic device as claimed in claim 2, wherein the plurality of first conductive lines and the plurality of second conductive lines receive a same voltage.

7. The electronic device as claimed in claim 2, wherein one of the plurality of second conductive lines presents an inverted L shape.

8. The electronic device as claimed in claim 2, wherein the plurality of second conductive lines present a grid shape.

9. The electronic device as claimed in claim 2, wherein in a cross-sectional view, the one of the plurality of second conductive lines is spaced apart from the one of the plurality of first driving lines by a dielectric layer.

10. The electronic device as claimed in claim 1, wherein the first direction is perpendicular to the second direction.

11. The electronic device as claimed in claim 1, wherein the plurality of first signal lines is configured to transmit scan signals.

12. The electronic device as claimed in claim 1, wherein the plurality of first signal lines is configured to transmit data signals.

13. The electronic device as claimed in claim 1, wherein lengths of two adjacent first driving lines are different.

14. The electronic device as claimed in claim 1, wherein lengths of two adjacent first driving lines and lengths of two adjacent first conductive lines show an opposite trend.

15. The electronic device as claimed in claim 1, further comprising a plurality of data lines disposed on the substrate and respectively extending along the second direction.

16. The electronic device as claimed in claim 15, wherein the plurality of data lines are parallel to but not overlapped with the plurality of first driving lines and the first conductive lines.

17. The electronic device as claimed in claim 15, wherein the plurality of data lines, the plurality of first driving lines, and the plurality of first conductive lines are located in the same layer.

18. The electronic device as claimed in claim 1, further comprising a plurality of thin film transistors, wherein the plurality of first signal lines are connected to gates of the plurality of thin film transistors.

19. The electronic device as claimed in claim 1, wherein in a cross-sectional view, one of the plurality of first signal lines and one of the plurality of first driving lines are electrically connected to each other by a conductive layer.

20. The electronic device as claimed in claim 1, wherein in a cross-sectional view, the one of the plurality of first conductive lines is spaced apart from the one of the plurality of first driving lines by a dielectric layer.
